(19) United States
(12) Patent Application Publication
(10) Pub. No.: US 2024/0179831 A1
(43) Pub. Date: May 30, 2024

(54) ELECTRONIC MODULE AND ELECTRONIC DEVICE

(71) Applicant: CANON KABUSHIKI KAISHA, Tokyo (JP)

(72) Inventors: HIROYUKI YAMAGUCHI, Kanagawa (JP); MOMOKA UMEGAE, Kanagawa (JP)

(21) Appl. No.: 18/515,661

(22) Filed: Nov. 21, 2023

(30) Foreign Application Priority Data
Nov. 28, 2022 (JP) 2022-189005

(51) Int. Cl. H05K 1/02; H05K 1/11

(52) U.S. Cl. CPC H05K 1/0262; H05K 1/112; H04N 25/709; H05K 2201/0335; H05K 2201/0776

(57) ABSTRACT

An electronic module includes a plurality of loads, a first wiring portion, a second wiring portion, a power source unit, and a feedback portion. The first wiring portion includes a plurality of first portions to which the plurality of loads are respectively connected, and a plurality of second portions each closest to a corresponding one of the plurality of first portions. The second wiring portion is connected to the plurality of second portions. The power source unit includes a feedback terminal, an output terminal, and a power source circuit. In the first wiring portion, a minimum path length from each of the plurality of second portions to the corresponding one of the plurality of first portions is smaller than 1/2 of a minimum path length from a part of the first wiring portion connected to the output terminal to the corresponding one of the plurality of first portions.

### BACKGROUND OF THE INVENTION

### Field of the Invention

The present disclosure relates to a technique of supplying a voltage to a load.

### Description of the Related Art

Japanese Patent Laid-Open No. 2014-27267 discloses a printed circuit board including a power source circuit, a load, and a printed wiring board including power source wiring used for supplying a voltage from the power source circuit to the load. In addition, Japanese Patent Laid-Open No. 2010-130799 discloses a power source device that supplies a voltage from a regulator device to a plurality of devices. Japanese Patent Laid-Open No. 2010-130799 discloses that the regulator device includes an output terminal and a feedback terminal and that a voltage output from the output terminal is adjusted on the basis of the voltage supplied to the feedback terminal.

However, the voltage supplied to each of a plurality of loads decreases with respect to the voltage at the output terminal due to the wiring resistance of the path from the output terminal of the regulator device to each of the plurality of loads. Therefore, voltages respectively supplied to the plurality of loads can be different from each other. It is desired that the voltage supplied to each of the plurality of loads falls within an allowable range even in the case of occurrence of voltage fluctuation.

### SUMMARY OF THE INVENTION

According to one aspect of the present disclosure, an electronic module includes a plurality of loads, a first wiring portion, a second wiring portion, a power source unit, and a feedback portion. The first wiring portion is used for supplying a voltage to the plurality of loads. The first wiring portion includes a plurality of first portions to which the plurality of loads are respectively connected, and a plurality of second portions each closest to a corresponding one of the plurality of first portions. The second wiring portion is connected to the plurality of second portions. The power source unit includes a feedback terminal, an output terminal connected to the first wiring portion, and a power source circuit configured to control a voltage to be output from the output terminal on a basis of a feedback voltage supplied to the feedback terminal. The feedback portion is configured to supply a voltage corresponding to a voltage generated in a predetermined portion of the second wiring portion to the feedback terminal as the feedback voltage. In the first wiring portion, a minimum path length from each of the plurality of second portions to the corresponding one of the plurality of first portions is smaller than ½ of a minimum path length from a part of the first wiring portion connected to the output terminal to the corresponding one of the plurality of first portions.

Further features of the present invention will become apparent from the following description of exemplary embodiments with reference to the attached drawings.

### BRIEF DESCRIPTION OF THE DRAWINGS

FIG. 1 is an explanatory diagram of an image pickup apparatus serving as an example of an electronic device according to a first embodiment.

FIG. 2A is a perspective view of a processing module according to the first embodiment.

FIG. 2B is a top view of the processing module according to the first embodiment.

FIG. 3A is a circuit diagram of a power source unit according to the first embodiment.

FIG. 3B is a circuit diagram of a power source unit of a modification example of the first embodiment.

FIG. 4A is a schematic view of a path of a main wiring portion according to the first embodiment.

FIG. 4B is a schematic view of a path of the main wiring portion according to the first embodiment.

FIG. 4C is a schematic view of a path of the main wiring portion according to the first embodiment.

FIG. 4D is a schematic view of a path of the main wiring portion according to the first embodiment.

FIG. 5 is an explanatory diagram illustrating a result of simulation by a computer according to Example 1.

FIG. 6A is a perspective view of a processing module according to a second embodiment.

FIG. 6B is a top view of the processing module according to the second embodiment.

FIG. 7A is a schematic view of a path of a main wiring portion according to the second embodiment.

FIG. 7B is a schematic view of a path of the main wiring portion according to the second embodiment.

FIG. 7C is a schematic view of a path of the main wiring portion according to the second embodiment.

FIG. 7D is a schematic view of a path of the main wiring portion according to the second embodiment.

FIG. 8 is an explanatory diagram illustrating a result of simulation by a computer according to Example 2.

FIG. 9A is a perspective view of a processing module according to a third embodiment.

FIG. 9B is an exploded perspective view of the processing module according to the third embodiment.

FIG. 10 is an explanatory diagram of samples for which simulation was performed by a computer according to Example 3.

FIG. 11 is an explanatory diagram illustrating a result of simulation by the computer according to Example 3.

FIG. 12A is a perspective view of a processing module according to Comparative Example 1.

FIG. 12B is a perspective view of a processing module according to Comparative Example 2.

FIG. 12C is an explanatory diagram of a result of simulation by a computer according to Comparative Examples 1 and 2.

### DESCRIPTION OF THE EMBODIMENTS

Exemplary embodiments of the present disclosure will be described in detail below with reference to drawings.

### First Embodiment

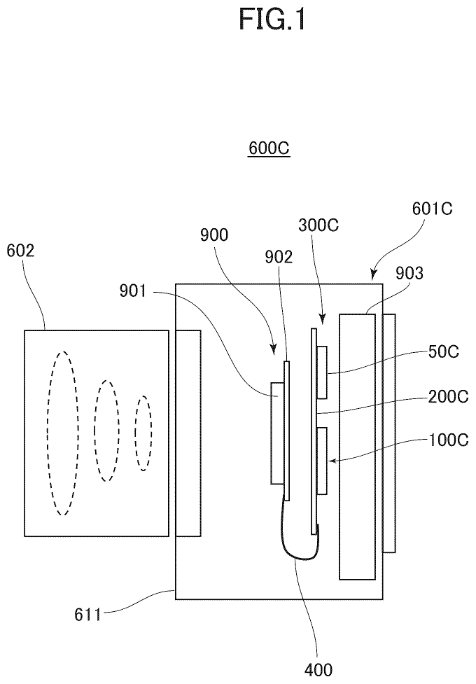

FIG. 1 is an explanatory diagram of a digital camera 600C that is an image pickup apparatus serving as an example of an electronic device according to a first embodiment. The digital camera 600C that is an image pickup apparatus is a digital camera of a lens-replacing type, and includes a camera body 601C. A lens unit (lens barrel) 602 including a lens is attachable to and detachable from the camera body 601C. The camera body 601C includes a casing 611 and a processing module 300C and a sensor module 900 that are disposed inside the casing 611. The processing module 300C is an example of an electronic module, and is constituted by a printed circuit board. The processing module 300C and the sensor module 900 are electrically interconnected via a cable 400. A battery 903 is disposed inside the casing 611. The battery 903 is a power source that supplies power to the processing module 300C, the sensor module 900, and the like.

The sensor module 900 includes an image sensor 901 that is an imaging device, and a wiring board 902. The wiring board 902 is a printed wiring board and a rigid wiring board.

The image sensor 901 is mounted on the wiring board 902. The image sensor 901 is, for example, a complementary metal oxide semiconductor: CMOS image sensor, or a charge-coupled device: CCD image sensor. The image sensor 901 has a function of converting light incident thereon through the lens unit 602 into an electric signal.

The processing module 300C includes a power source unit 50C, a load unit 100C, and a wiring board 200C. The wiring board 200C is a printed wiring board, and is a rigid wiring board. The power source unit 50C and the load unit 100C are mounted on the wiring board 200C.

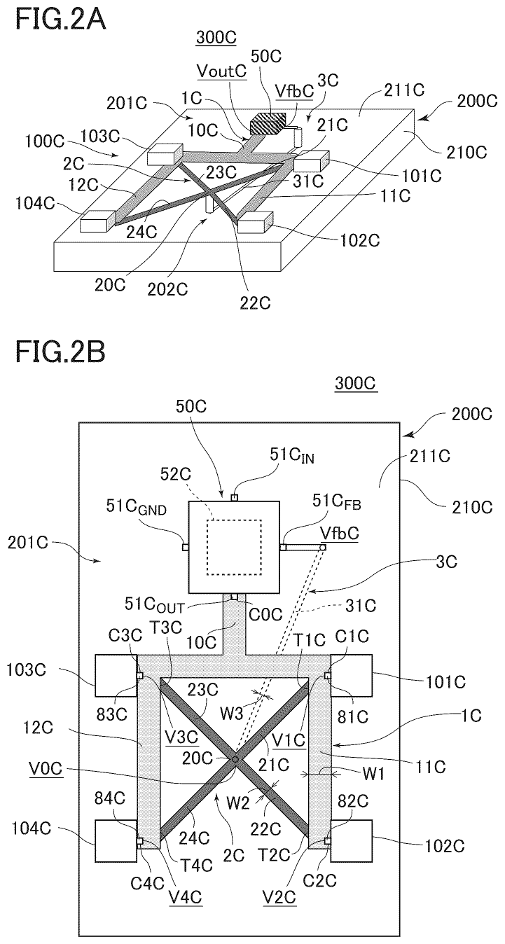

FIG. 2A is a perspective view of the processing module 300C according to the first embodiment. FIG. 2B is a top view of the processing module 300C according to the first embodiment. The wiring board 200C includes an insulating substrate 210C and at least one conductor layer. The at least one conductor layer includes two conductor layers 201C and 202C. The conductor layer 201C is an example of a first conductor layer, and the conductor layer 202C is an example of a second conductor layer. The conductor layer 201C is, for example, a surface layer positioned on the outside of the insulating substrate 210C, that is, positioned on a main surface 211C of the insulating substrate 210C. The conductor layer 202C is, for example, a conductor layer positioned on the outside or the inside of the insulating substrate 210C, such as an inner layer positioned on the inside.

The power source unit 50C and the load unit 100C are disposed on the main surface 211C of the insulating substrate 210C. That is, the power source unit 50C and the load unit 100C are disposed on the conductor layer 201C. The insulating substrate 210C is formed from an insulator having an electrical insulating property, for example, glass epoxy resin. A conductor pattern constituting various lines such as a power supply line, a grounding line, and a signal line is disposed in each of the conductor layers 201C and 202C. The conductor pattern is formed from metal such as copper or gold.

The load unit 100C includes a plurality of loads. The plurality of loads include, for example, a load 101C, a load 102C, a load 103C, and a load 104C. In the first embodiment, the plurality of loads are the load 101C, the load 102C, the load 103C, and the load 104C. To be noted, the number of loads is not limited to four as long as two or more loads are provided.

The load 101C is an example of a first load, the load 102C is an example of a second load, the load 103C is an example of a third load, and the load 104C is an example of a fourth load. The loads 101C to 104C are each a load circuit. In the first embodiment, the loads 101C to 104C are each a semiconductor device. To be noted, two or more of the loads 101C to 104C may be load circuits included in one semiconductor device.

The loads 101C and 103C are, for example, digital signal processors, and have a function of generating image data by obtaining an electric signal from the image sensor 901 and performing processing to correct the obtained electric signal. The loads 102C and 104C are, for example, each a memory device such as a dynamic random access memory: DRAM, and have a function of communicating electric signals with the loads 101C and 103C and temporarily storing data such as image data.

The processing module 300C includes a main wiring portion 1C that is a main part of a power source wiring portion for supplying a voltage to each of the plurality of loads 101C to 104C of the load unit 100C, and an unillustrated grounding line. The main wiring portion 1C is an example of a first wiring portion. The main wiring portion 1C and the unillustrated grounding line are included in the wiring board 200C.

The main wiring portion 1C is used for supplying a voltage output from the power source unit 50C to the loads 101C to 104C. That is, the main wiring portion 1C is used for supplying a current to each of the loads 101C and 102C. The main wiring portion 1C includes a main line 10C, and two main lines 11C and 12C branching from the main line 10C.

The power source unit 50C is an integrated circuit: IC including an input terminal 51C_{IN}, an output terminal 51C_{OUT}, a feedback terminal 51C_{FB}, a ground terminal 51C_{GND}, and a power source circuit 52C, and is, for example, a series regulator.

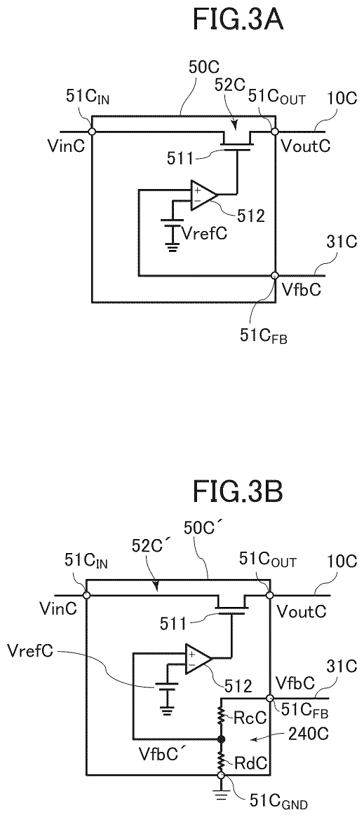

FIG. 3A is a circuit diagram of the power source unit 50C according to the first embodiment. The input terminal 51C_{IN} is electrically connected to the battery 903 of FIG. 1, and an input voltage VinC from the battery 903 is input to the input terminal 51C_{IN}. The output terminal 51C_{OUT} is mechanically and electrically connected to a connecting portion C0C of the main line 10C via a conductive bonding material such as solder. The ground terminal 51C_{GND} is mechanically and electrically connected to the unillustrated grounding line via a conductive bonding material such as solder. A feedback voltage VfbC is supplied to the feedback terminal 51C_{FB}. The power source circuit 52C controls an output voltage VoutC output from the output terminal 51C_{OUT} on the basis of the feedback voltage VfbC. As a result of this, the output voltage VoutC required for operation of the loads 101C to 104C is output from the output terminal 51C_{OUT} to the main wiring portion 1C.

The power source circuit 52C includes an error amplification circuit 512 and a control transistor 511. The error amplification circuit 512 includes an inversion input terminal and a non-inversion input terminal. The feedback voltage VfbC supplied to the feedback terminal 51C_{FB} is input to the non-inversion input terminal of the error amplification circuit 512. A reference voltage VrefC is input to the inversion input terminal of the error amplification circuit 512. The reference voltage VrefC is a voltage serving as a reference for determining the output voltage VoutC.

The error amplification circuit 512 has a function of amplifying the voltage difference between the feedback voltage VfbC and the reference voltage VrefC by a predetermined amplification rate and outputting a voltage obtained by amplifying the voltage difference. The output voltage of the error amplification circuit 512 is input to the gate electrode of the control transistor 511.

The control transistor 511 is, for example, a field effect transistor: FET. An input voltage VinC is applied to a source electrode of the control transistor 511, the output voltage of the error amplification circuit 512 is applied to a gate electrode of the control transistor 511, and the output voltage VoutC is output from the drain electrode of the control transistor 511. The control transistor 511 controls the ON resistance in accordance with the gate electrode.

To be noted, the power source unit 50C may include a voltage divider circuit. FIG. 3B is a circuit diagram of a power source unit 50C′ of a modification example of the first embodiment. The power source unit 50C′ of the modification example includes a power source circuit 52C′. The power source circuit 52C′ includes the error amplification circuit 512, the control transistor 511, and a voltage divider circuit 240C. The voltage divider circuit 240C includes a resistor portion RcC and a resistor portion RdC. The resistor portion RcC and the resistor portion RdC are each at least one resistor element. The resistor portion RcC is connected to the feedback terminal 51C_{FB}, and the resistor portion RdC is connected to the resistor portion RcC in series. The resistor portion RdC is connected to the ground terminal 51C_{GND} to which the grounding line is connected.

As a result of this, a voltage between the feedback voltage VfbC and the ground voltage is generated between the resistor portions RcC and RdC due to the voltage division by the resistor portions RcC and RdC. The voltage generated between the resistor portions RcC and RdC is supplied to the error amplification circuit 512 as a feedback voltage VfbC′. As described above, the feedback voltage VfbC supplied to the feedback terminal 51C_{FB} is divided into the feedback voltage VfbC′ by the voltage divider circuit 240C.

The feedback voltage VfbC′ is input to the non-inversion input terminal of the error amplification circuit 512. The reference voltage VrefC is input to the inversion input terminal of the error amplification circuit 512.

The error amplification circuit 512 has a function of amplifying the voltage difference between the feedback voltage VfbC′ and the reference voltage VrefC by a predetermined amplification rate and outputting a voltage obtained by amplifying the voltage difference. The output voltage of the error amplification circuit 512 is input to the gate electrode of the control transistor 511.

As illustrated in FIGS. 2A and 2B, the main wiring portion 1C is a part of the wiring included in the wiring board 200C, and is formed in the conductor layer 201C. In the wiring board 200C, the main wiring portion 1C may be formed to be present in both the conductor layer 201C and the conductor layer 202C different from the conductor layer 201C, but is preferably formed only in the conductor layer 201C on which the power source unit 50C and the load unit 100C are mounted, from the viewpoint of reducing the wiring resistance.

In the first embodiment, the loads 101C to 104C are each a semiconductor package. The load 101C includes a power source terminal 81C. The load 102C includes a power source terminal 82C. The load 103C includes a power source terminal 83C. The load 104C includes a power source terminal 84C. To be noted, the loads 101C to 104C each include an unillustrated ground terminal and an unillustrated signal terminal.

The loads 101C to 104C operate by a direct current voltage. The voltage most suitable for operation is the same for the loads 101C and 102C and is, for example, 1 V. In the first embodiment, the plurality of loads 101C to 104C are connected to the main wiring portion 1C. Therefore, the main wiring portion 1C includes a connecting portion C1C to which the power source terminal 81C of the load 101C is connected, a connecting portion C2C to which the power source terminal 82C of the load 102C is connected, a connecting portion C3C to which the power source terminal 83C of the load 103C is connected, and a connecting portion C4C to which the power source terminal 84C of the load 104C is connected. The plurality of connecting portions C1C to C4C are each an example of a first portion. The plurality of connecting portions C1C to C4C are each, for example, a power source pad. In the example of the first embodiment, the connecting portions C1C and C2C are included in the main line 11C, and the connecting portions C3C and C4C are included in the main line 12C. The unillustrated ground terminal included in each of the loads 101C to 104C is connected to an unillustrated grounding line.

As described above, the loads 101C to 104C are electrically connected to the power source unit 50C via the main wiring portion 1C and the grounding line, and operate by receiving a direct current voltage based on the ground applied from the power source unit 50C. The most suitable operation voltage is the same for all the loads 101C to 104C and is, for example, 1V. The most suitable operation voltage for operation of the loads 101C to 104C is used as a standard voltage.

For each of the loads 101C to 104C, an allowable voltage fluctuation range is determined for the standard voltage. The allowable voltage fluctuation range is, for example, a range of ±30 mV for 1 V. The allowable voltage fluctuation range is a range of voltage in which the load can stably operate. In the description below, the allowable voltage fluctuation range will be simply referred to as an allowable range. In the case where the voltage applied to the load is out of the allowable range beyond the upper limit voltage or the lower limit voltage of the allowable range, there is a possibility that malfunction of the load occurs.

In the first embodiment, the loads 101C and 102C are connected to the main line 11C, and the loads 103C and 104C are connected to the main line 12C. The loads 101C and 102C are connected to the main line 11C in this order in a direction of moving away from the output terminal 51C_{OUT} of the power source unit 50C along the path of the main wiring portion 1C. In addition, the loads 103C and 104C are connected to the main line 12C in this order in the direction of moving away from the output terminal 51C_{OUT} of the power source unit 50C along the path of the main wiring portion 1C. That is, in the main line 11C, the loads 101C and 102C are arranged in series in this order along the path of the main wiring portion 1C. In addition, in the main line 12C, the loads 103C and 104C are arranged in series in this order along the path of the main wiring portion 1C. Therefore, the connecting portions C1C and C2C are arranged at an interval along the main wiring portion 1C in the main line 11C, and the connecting portions C3C and C4C are arranged at an interval along the path of the main wiring portion 1C in the main line 12C.

In recent years, improvement in the performance of digital cameras has advanced, and there is an increasing tendency in the current consumption of semiconductor devices included in the digital cameras. For portable products such as digital cameras, reduction of battery consumption is important. Therefore, the operation volage of semiconductor devices has been increasingly reduced. In accordance with the reduction of voltage, the allowable range set for avoiding malfunction of semiconductor devices has become narrower. Meanwhile, in portable devices such as digital cameras, miniaturization is desired, and thus the wiring density of wiring boards has increased, and miniaturization of wiring has advanced.

The plurality of loads 101C to 104C are each a load circuit that operates at a low voltage (1 V or less, for example, 1 V), and therefore voltage drop by wiring resistance in the main wiring portion 1C cannot be neglected. Although increasing the area of the main wiring portion 1C to reduce the wiring resistance can be considered, there is a limit in the increase in the area of the main wiring portion 1C for highly densely mounting electronic parts on the wiring board 200C and highly densely providing the wiring of the wiring board 200C.

Therefore, in the first embodiment, the processing module 300C includes a sub wiring portion 2C directly connected to the main wiring portion 1C, and a feedback portion 3C. The sub wiring portion 2C is an example of a second wiring portion. The sub wiring portion 2C is included in the wiring board 200C. The feedback portion 3C is connected to a predetermined portion 20C of the sub wiring portion 2C, and is configured to feed back a voltage corresponding to a voltage V0C generated in the predetermined portion 20C to the feedback terminal 51C_{FB} of the power source unit 50C. The wiring resistance of the wiring included in the sub wiring portion 2C per unit path length is set to be higher than the wiring resistance of the wiring included in the main wiring portion 1C per unit path length.

The main wiring portion 1C includes a plurality of proximity portions T1C to T4C of the same number as the plurality of connecting portions C1C to C4C. The proximity portions T1C to T4C are each an example of a second portion. The sub wiring portion 2C is connected to the plurality of proximity portions T1C to T4C. That is, the plurality of proximity portions T1C to T4C are short-circuited via the sub wiring portion 2C.

Here, the voltage applied to the power source terminal 81C of the load 101C, that is, the voltage of the connecting portion C1C will be denoted by V1C. The voltage applied to the power source terminal 82C of the load 102C, that is, the voltage of the connecting portion C2C will be denoted by V2C. The voltage applied to the power source terminal 83C of the load 103C, that is, the voltage of the connecting portion C3C will be denoted by V3C. The voltage applied to the power source terminal 84C of the load 104C, that is, the voltage of the connecting portion C4C will be denoted by V4C.

The proximity portion T1C is the closest to the connecting portion C1C corresponding thereto among the plurality of connecting portions C1C to C4C on the path of the main wiring portion 1C. The proximity portion T2C is the closest to the connecting portion C2C corresponding thereto among the plurality of connecting portions C1C to C4C on the path of the main wiring portion 1C. The proximity portion T3C is the closest to the connecting portion C3C corresponding thereto among the plurality of connecting portions C1C to C4C on the path of the main wiring portion 1C. The proximity portion T4C is the closest to the connecting portion C4C corresponding thereto among the plurality of connecting portions C1C to C4C on the path of the main wiring portion 1C.

The proximity portion T1C is a portion close to the connecting portion C1C, that is, a portion in the vicinity of the connecting portion C1C. The proximity portion T2C is a portion close to the connecting portion C2C, that is, a portion in the vicinity of the connecting portion C2C. The proximity portion T3C is a portion close to the connecting portion C3C, that is, a portion in the vicinity of the connecting portion C3C. The proximity portion T4C is a portion close to the connecting portion C4C, that is, a portion in the vicinity of the connecting portion C4C.

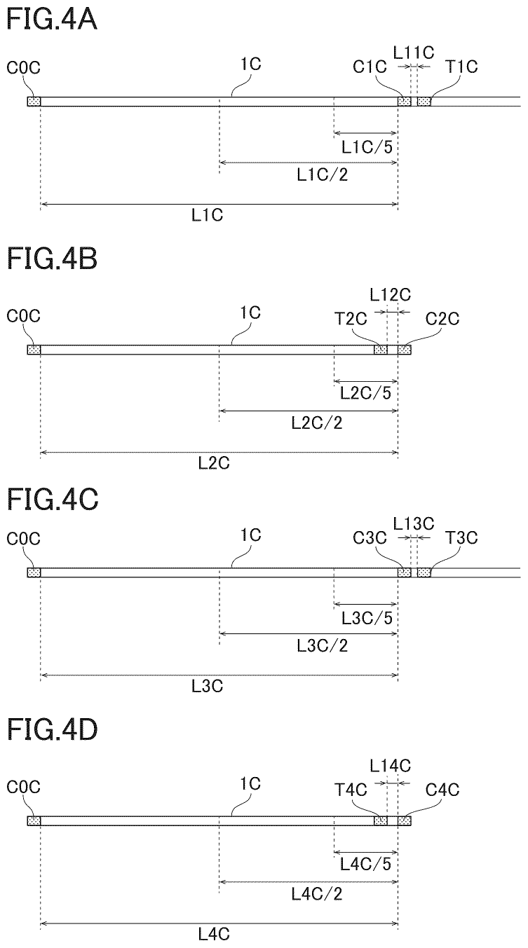

A preferable range in which the proximity portions T1C and T4C are respectively close to the connecting portions C1C to C4C will be described below. FIGS. 4A to 4D are schematic diagrams illustrating paths of the main wiring portions 1C according to the first embodiment. To be noted, in FIGS. 4A to 4D, the path of the main wiring portion 1C is illustrated as a straight line for the sake of convenience of description.

In the main wiring portion 1C, the minimum path length from each of the plurality of proximity portions T1C to T4C to the corresponding one of the connecting portions is preferably smaller than ½ of the minimum path length from the connecting portion C0C to which the output terminal 51C_{OUT} is connected to the corresponding one of the connecting portions.

In addition, in the main wiring portion 1C, the minimum path length from each of the plurality of proximity portions T1C to T4C to the corresponding one of the connecting portions is more preferably smaller than ⅕ of the minimum path length from the connecting portion C0C to which the output terminal 51C_{OUT} is connected to the corresponding one of the connecting portions.

That is, the connecting portion corresponding to the proximity portion T1C is the connecting portion C1C, the connecting portion corresponding to the proximity portion T2C is the connecting portion C2C, the connecting portion corresponding to the proximity portion T3C is the connecting portion C3C, and the connecting portion corresponding to the proximity portion T4C is the connecting portion C4C.

Further, as illustrated in FIG. 4A, a minimum path length L11C from the proximity portion T1C to the connecting portion C1C is preferably smaller than ½, more preferably smaller than ⅕ of a minimum path length L1C from the connecting portion C0C to the connecting portion C1C.

In addition, as illustrated in FIG. 4B, a minimum path length L12C from the proximity portion T2C to the connecting portion C2C is preferably smaller than ½, more preferably smaller than ⅕ of a minimum path length L2C from the connecting portion C0C to the connecting portion C2C.

In addition, as illustrated in FIG. 4C, a minimum path length L13C from the proximity portion T3C to the connecting portion C3C is preferably smaller than ½, more preferably smaller than ⅕ of a minimum path length L3C from the connecting portion C0C to the connecting portion C3C.

In addition, as illustrated in FIG. 4D, a minimum path length L14C from the proximity portion T4C to the connecting portion C4C is preferably smaller than ½, more preferably smaller than ⅕ of a minimum path length L4C from the connecting portion C0C to the connecting portion C4C.

To be noted, in FIGS. 4A to 4D, although the minimum path lengths L1C to L4C are illustrated as equal, these are just illustrated as equal for the sake of convenience of description, and the actual minimum path lengths L1C to L4C do not have to be equal to each other.

The proximity portions T1C to T4C are preferably positioned upstream of the corresponding ones of the connecting portions C1C to C4C in the flow direction of the current, but the configuration is not limited to this. For example, the proximity portions T1C and T3C may be respectively positioned downstream of the connecting portions C1C and C3C in the flow direction of the current. That is, it suffices as long as the proximity portions T1C to T4C are respectively close to the connecting portions C1C to C4C.

The feedback portion 3C includes a feedback line 31C, and a voltage corresponding to the voltage V0C generated in the predetermined portion 20C of the sub wiring portion 2C to the feedback terminal 51C_{FB} as the feedback voltage VfbC. In the first embodiment, the feedback portion 3C is the feedback line 31C. The feedback line 31C is included in the wiring board 200C.

The feedback line 31C is disposed between the predetermined portion 20C of the sub wiring portion 2C and the feedback terminal 51C_{FB}, and is directly connected to the predetermined portion 20C of the sub wiring portion 2C and the feedback terminal 51C_{FB}. That is, a first end of the feedback line 31C is directly connected to the predetermined portion 20C of the sub wiring portion 2C, and a second end of the feedback line 31C is directly connected to the feedback terminal 51C_{FB}.

To be noted, the feedback portion 3C may include, for example, an unillustrated voltage divider circuit having a configuration similar to that of the voltage divider circuit 240C illustrated in FIG. 3B. In this case, the second end of the feedback line 31C is connected to the feedback terminal 51C_{FB} via the unillustrated voltage divider circuit. The unillustrated voltage divider circuit supplies a voltage obtained by dividing the voltage V0C to the feedback terminal 51C_{FB} as a voltage corresponding to the voltage V0C.

Since a current as large as the current flowing in the main wiring portion 1C does not have to be supplied to the feedback line 31C, a width W3 of the feedback line 31C is preferably smaller than a width W1 of each of the main lines 10C, 11C, and 12C included in the main wiring portion 1C. That is, preferably W3<W1 holds.

According to the above-described configuration of the feedback portion 3C, a voltage obtained by subtracting a value of voltage reduction derived from the wiring resistance of the feedback line 31C from the voltage V0C generated in the predetermined portion 20C of the sub wiring portion 2C is supplied to the feedback terminal 51C_{FB} as the feedback voltage VfbC.

As described above, a voltage corresponding to the voltage V0C is supplied to the feedback terminal 51C_{FB} as the feedback voltage VfbC. The power source circuit 52C controls the output voltage VoutC output from the output terminal 51C_{OUT} on the basis of the feedback voltage VfbC supplied to the feedback terminal 51C_{FB}.

To be noted, the current flowing in the feedback line 31C is, for example, about several tens of μA, which is an extremely small value as compared with the current flowing in the main wiring portion 1C, and therefore the voltage reduction derived from the wiring resistance of the feedback line 31C can be neglected. In such a case, the voltage corresponding to the voltage V0C is the voltage V0C.

As described above, according to the first embodiment, since the plurality of the proximity portions T1C to T4C respectively close to the plurality of connecting portions C1C to C4C are short-circuited at the sub wiring portion 2C, a current flows from the high-potential side to the low-potential side via the sub wiring portion 2C, and as a result, the potential difference between the plurality of connecting portions C1C to C4C, that is, the potential difference between the plurality of loads 101C to 104C can be reduced. Therefore, the voltages V1C to V4C applied to the loads 101C to 104C become close to each other.

Further, since a voltage corresponding to the voltage V0C of the predetermined portion 20C of the sub wiring portion 2C is fed back to the feedback terminal 51C_{FB}, the voltages V1C to V4C applied to the loads 101C to 104C can be kept within the respective allowable ranges of the loads 101C to 104C. Therefore, a margin is secured for each of the voltages V1C to V4C with respect to the upper limit voltage or the lower limit voltage of the allowable range of each of the loads 101C to 104C. As a result of this, the voltages V1C to V4C are stably supplied to the loads 101C to 104C, and thus the loads 101C to 104C operate stably.

The sub wiring portion 2C includes a plurality of branch lines 21C to 24C of the same number as the plurality of proximity portions T1C to T4C. That is, the sub wiring portion 2C includes four branch lines 21C to 24C. The plurality of branch lines 21C to 24C are respectively directly connected to the plurality of proximity portions T1C to T4C. Further, the plurality of branch lines 21C to 24C are connected to each other at the predetermined portion 20C.

That is, the first end of each of the branch lines 21C to 24C is directly connected to the corresponding one of the proximity portions, and the respective second ends of the plurality of branch lines 21C to 24C are connected to each other at the predetermined portion 20C.

Specifically, the first end of the branch line 21C is directly connected to the proximity portion T1C, the first end of the branch line 22C is directly connected to the proximity portion T2C, the first end of the branch line 23C is directly connected to the proximity portion T3C, and the first end of the branch line 24C is directly connected to the proximity portion T4C. The second end of the branch line 21C, the second end of the branch line 22C, the second end of the branch line 23C, and the second end of the branch line 24C are connected to each other at the predetermined portion 20C.

The current flowing in each of the branch lines 21C to 24C is preferably smaller than the current flowing in the main wiring portion 1C. Therefore, a width W2 of each of the plurality of branch lines 21C to 24C is preferably smaller than the width W1 of each of the main lines 10C, 11C, and 12C. That is, W2<W1 preferably holds. In other words, the wiring resistance of each of the branch lines 21C to 24C is preferably higher than the wiring resistance of the main wiring portion 1C.

In addition, the current flowing in the feedback line 31C is preferably smaller than the current flowing in each of the branch lines 21C to 24C. Therefore, the width W3 of the feedback line 31C is preferably smaller than the width W2 of each of the plurality of branch lines 21C to 24C. That is, W3<W2 preferably holds. In other words, the wiring resistance of the feedback line 31C is preferably higher than the wiring resistance of each of the branch lines 21C to 24C.

In addition, the electrical resistance of each of the plurality of branch lines 21C to 24C is preferably 138 mΩ or less. As a result of this, the difference between the voltages V1C to V4C can be reduced more effectively.

In addition, the main wiring portion 1C and the sub wiring portion 2C are disposed in the conductor layer 201C. At least part of the feedback line 31C is disposed in the conductor layer 202C. That is, the feedback line 31C includes a wiring portion disposed in the conductor layer 201C, a wiring portion disposed in the conductor layer 202C, and a via line interconnecting the conductor layer 201C and 202C. As described above, as a result of part of the feedback line 31C being disposed in the conductor layer 202C different from the conductor layer 201C, the wiring board 200C can be miniaturized.

To be noted, although the loads 101C to 104C are preferably disposed on the conductor layer 201C on which the power source unit 50C is disposed, at least one of the loads 101C to 104C may be disposed on the conductor layer serving as a surface layer opposite to the conductor layer 201C.

A result of computer simulation performed in a circuit configuration of the processing module 300C according to the first embodiment will be described below.

### Example 1

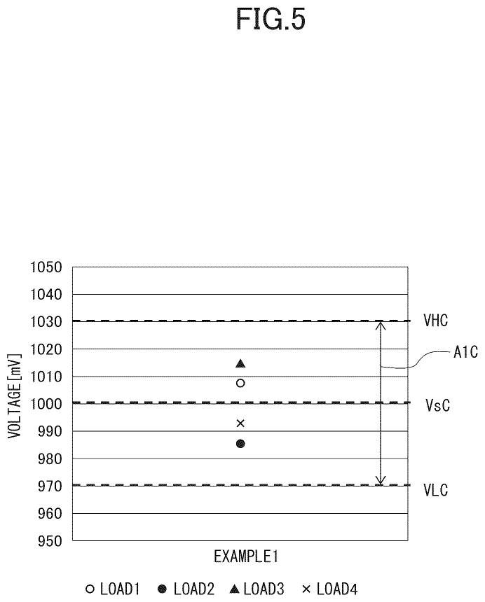

FIG. 5 is an explanatory diagram illustrating a result of simulation by a computer according to Example 1. For the simulation, ANSYS Electronics Desktop 2020 R2 Circuit Design was used. In the simulation, each parameter was set as follows.

The standard voltage VsC of each of the loads 101C to 104C was set to 1 V, that is, 1000 mV. An allowable range A1C of each of the loads 101C to 104C was set to a range of ±30 mV from the standard voltage VsC. That is, a lower limit voltage VLC of the allowable range A1C of each of the loads 101C to 104C was set to 970 mV, and an upper limit voltage VHC of the allowable range A1C of each of the loads 101C to 104C was set to 1030 m V.

The wiring resistance of a partial line from a connecting portion of the main line 11C with the main line 10C to the connecting portion C1C was set to 15 mω. In addition, the wiring resistance of a partial line in the main line 11C from the connecting portion C1C to the connecting portion C2C was set to 30 mω. The wiring resistance of a partial line from a connecting portion of the main line 12C with the main line 10C to the connecting portion C3C was set to 10 mω. In addition, the wiring resistance of a partial line in the main line 12C from the connecting portion C3C to the connecting portion C4C was set to 25 mω. The operation current of each of the loads 101C to 104C was set to 1 A. In addition, the wiring resistance of each of the branch lines 21C to 24C was set to 60 mω.

In FIG. 5, the voltage V1C applied to the load 101C corresponds to “LOAD 1”, the voltage V2C applied to the load 102C corresponds to “LOAD 2”, the voltage V3C applied to the load 103C corresponds to “LOAD 3”, and the voltage V4C applied to the load 104C corresponds to “LOAD 4”.

### Comparative Examples 1 and 2

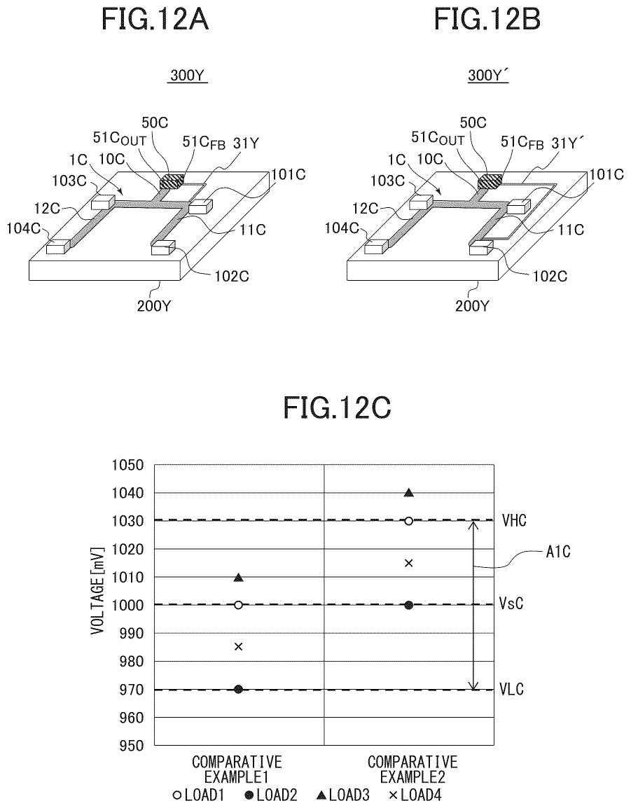

FIG. 12A is a perspective view of a processing module 300Y according to Comparative Example 1. FIG. 12B is a perspective view of a processing module 300Y′ according to Comparative Example 2. To be noted, in the configurations of the processing modules 300Y and 300Y′ of Comparative Examples 1 and 2, elements substantially the same as in Example 1 will be denoted by the same reference signs and description thereof will be omitted.

As illustrated in FIG. 12A, the processing module 300Y of Comparative Example 1 includes a wiring board 200Y, and the power source unit 50C and the plurality of loads 101C to 104C that are mounted on the wiring board 200Y. The wiring board 200Y includes the main wiring portion 1C including the main lines 10C to 12C, and a feedback line 31Y. The wiring board 200Y does not include the sub wiring portion 2C. The feedback line 31Y is connected to the vicinity of a connecting portion to which the load 101C is connected in the main line 11C, and is configured to feed back the voltage of the load 101C to the feedback terminal 51C_{FB}.

As illustrated in FIG. 12B, the processing module 300Y′ of Comparative Example 2 includes a wiring board 200Y′, and the power source unit 50C and the plurality of loads 101C to 104C that are mounted on the wiring board 200Y′. The wiring board 200Y′ includes the main wiring portion 1C including the main lines 10C to 12C, and a feedback line 31Y′. The wiring board 200Y′ does not include the sub wiring portion 2C. The feedback line 31Y′ is connected to the vicinity of a connecting portion to which the load 102C is connected in the main line 11C, and is configured to feed back the voltage of the load 102C to the feedback terminal 51C_{FB}.

FIG. 12C is an explanatory diagram illustrating results of simulation by a computer according to Comparative Examples 1 and 2. For the simulation, ANSYS Electronics Desktop 2020 R2 Circuit Design was used. In the simulation, each parameters was set as follows.

The standard voltage VsC of each of the loads 101C to 104C was set to 1 V, that is, 1000 mV. The allowable range A1C of each of the loads 101C to 104C was set to a range of ±30 mV from the standard voltage VsC. That is, the lower limit voltage VLC of the allowable range A1C of each of the loads 101C to 104C was set to 970 mV, and the upper limit voltage VHC of the allowable range A1C of each of the loads 101C to 104C was set to 1030 mV.

The wiring resistance of a partial line from a connecting portion of the main line 11C with the main line 10C to a connecting portion with the load 101C was set to 15 mω. In addition, the wiring resistance of a partial line from the connecting portion of the main line 11C with the load 101C to a connecting portion with the load 102C was set to 30 mω. The wiring resistance of a partial line from a connecting portion of the main line 12C with the main line 10C to a connecting portion with the load 103C was set to 10 mω. In addition, the wiring resistance of a partial line from the connecting portion of the main line 12C with the load 103C to a connecting portion with the load 104C was set to 25 mω. The operation current of each of the loads 101C to 104C was set to 1 A.

In FIG. 12C, the voltage applied to the load 101C corresponds to “LOAD 1”, the voltage applied to the load 102C corresponds to “LOAD 2”, the voltage applied to the load 103C corresponds to “LOAD 3”, and the voltage applied to the load 104C corresponds to “LOAD 4”.

As illustrated in FIG. 12C, in Comparative Example 1, the voltage applied to the load 101C is controlled to the standard voltage VsC, and is 1000 mV that is within the allowable range A1C. In addition, in Comparative Example 1, the voltage applied to the load 102C is 970 mV, which is the lower limit voltage VLC of the allowable range A1C and is barely within the allowable range A1C.

Meanwhile, in Comparative Example 2, the voltage applied to the load 102C is controlled to the standard voltage VsC, and is 1000 mV that is within the allowable range A1C. However, the voltage applied to the load 103C is 1040 mV and exceeds 1030 mV, which is the upper limit voltage VHC of the allowable range A1C.

In contrast, in Example 1, as can be seen from the simulation results illustrated in FIG. 5, the voltage difference between the loads 101C to 104C is smaller than in Comparative Examples 1 and 2. As a result of this, whereas the margin of the voltage of the load 102C with respect to the lower limit voltage VLC is 0 V in Comparative Example 1, a margin of 15 mV is secured for the voltage of the load 102C with respect to the lower limit voltage VLC in Example 1. In addition, the margin of the voltage of the load 103C with respect to the upper limit voltage VHC is also secured.

As described above, a current from the high-potential side to the low-potential side is generated between the loads 101C to 104C due to the sub wiring portion 2C, and as a result of this, the potential difference between the loads 101C to 104C can be reduced. Therefore, the voltages of the loads 101C to 104C can be kept within the allowable range A1C by feeding back the voltage of the predetermined portion 20C of the sub wiring portion 2C to the feedback terminal 51C_{FB}.

### Second Embodiment

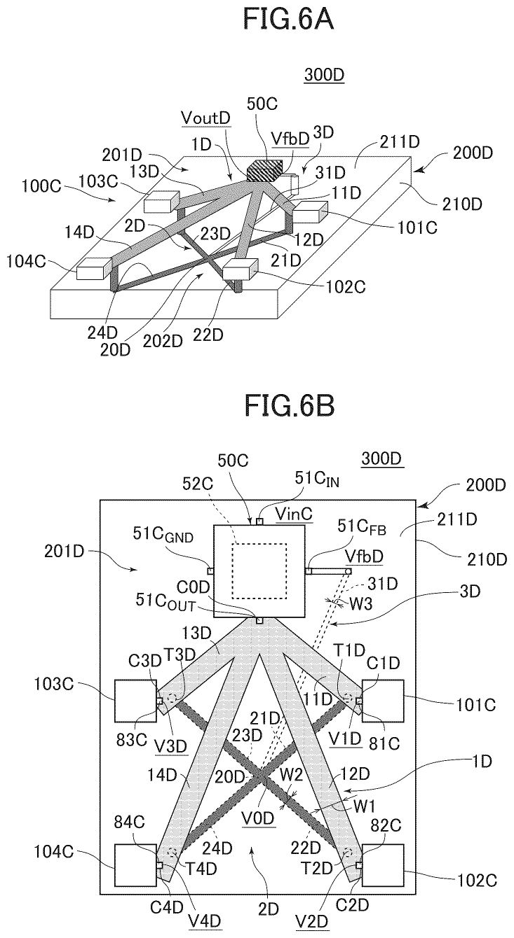

An electronic module included in an electronic device according to a second embodiment will be described. FIG. 6A is a perspective view of a processing module 300D according to the second embodiment. FIG. 6B is a top view of the processing module 300D according to the second embodiment. The electronic device of the second embodiment is, for example, a digital camera that is an image pickup apparatus. The digital camera of the second embodiment is different from the digital camera 600C of the first embodiment in that the processing module 300C is replaced by the processing module 300D. The elements of the digital camera of the second embodiment other than the processing module 300D are the same as the elements of the digital camera 600C of the first embodiment other than the processing module 300C, and therefore detailed description of the elements of the digital camera of the second embodiment other than the processing module 300D will be omitted. In addition, among the constituent parts of the processing module 300D, the same constituent parts as the constituent parts included in the processing module 300C will be denoted by the same reference signs used in the first embodiment, and description thereof will be omitted.

The processing module 300D includes the power source unit 50C, the load unit 100C, and a wiring board 200D. The configuration of the power source unit 50C and the load unit 100C is as described in the first embodiment, and the configuration of the wiring board 200D is different from the configuration of the wiring board 200C of the first embodiment. The wiring board 200D is a printed wiring board and a rigid wiring board. The power source unit 50C and the load unit 100C are mounted on the wiring board 200D.

The wiring board 200D includes an insulating substrate 210D, and at least one conductor layer. The at least one conductor layer includes two conductor layers 201D and 202D. The conductor layer 201D is an example of a first conductor layer, and the conductor layer 202D is an example of a second conductor layer. The conductor layer 201D is, for example, a surface layer positioned on the outside of the insulating substrate 210D, that is, positioned on a main surface 211D of the insulating substrate 210D. The conductor layer 202D is, for example, a conductor layer positioned on the outside or the inside of the insulating substrate 210D, such as an inner layer positioned on the inside.

The power source unit 50C and the load unit 100C are disposed on the main surface 211D of the insulating substrate 210D. That is, the power source unit 50C and the load unit 100C are disposed on the conductor layer 201D. The insulating substrate 210D is formed from an insulator having an electrical insulating property, for example, glass epoxy resin. A conductor pattern constituting various wirings such as a power supply line, a grounding line, and a signal line is disposed in each of the conductor layers 201D and 202D. The conductor pattern is formed from metal such as copper or gold.

The load unit 100C includes a plurality of loads. The plurality of loads include, for example, the load 101C, the load 102C, the load 103C, and the load 104C. In the second embodiment, the plurality of loads are the load 101C, the load 102C, the load 103C, and the load 104C. To be noted, the number of loads is not limited to four as long as two or more loads are provided.

The load 101C is an example of a first load, the load 102C is an example of a second load, the load 103C is an example of a third load, and the load 104C is an example of a fourth load. The loads 101C to 104C are each a load circuit. In the second embodiment, the loads 101C to 104C are each a semiconductor device. To be noted, two or more of the loads 101C to 104C may be load circuits included in one semiconductor device.

The processing module 300D includes a main wiring portion 1D that is a main part of a power source wiring portion for supplying a voltage to each of the plurality of loads 101C to 104C of the load unit 100C, and an unillustrated grounding line. The main wiring portion 1D is an example of a first wiring portion. The main wiring portion 1D and the unillustrated grounding line are included in the wiring board 200D.

The main wiring portion 1D is used for supplying a voltage output from the power source unit 50C to the loads 101C to 104C. That is, the main wiring portion 1D is used for supplying a current to each of the loads 101C and 102C. The main wiring portion 1D includes a plurality of main lines arranged in a star shape. In the second embodiment, the main wiring portion 1D includes four main lines 11D to 14D.

The power source unit 50C is an integrated circuit: IC including the input terminal 51C_{IN}, the output terminal 51C_{OUT}, the feedback terminal 51C_{FB}, the ground terminal 51C_{GND}, and the power source circuit 52C, and is, for example, a series regulator.

The input terminal 51C_{IN} of the power source unit 50C is electrically connected to the battery 903 of FIG. 1, and the input voltage VinC from the battery 903 is input to the input terminal 51C_{IN}. The output terminal 51C_{OUT} is mechanically and electrically connected to a connecting portion C0D of the main wiring portion 1D via a conductive bonding material such as solder. The plurality of main lines 11D and 14D are provided so as to extend radially from the connecting portion C0D. The ground terminal 51C_{GND} is mechanically and electrically connected to the unillustrated grounding line via a conductive bonding material such as solder. A feedback voltage VfbD is supplied to the feedback terminal 51C_{FB}. The power source circuit 52C controls an output voltage VoutD output from the output terminal 51C_{OUT} on the basis of the feedback voltage VfbD. As a result of this, the output voltage VoutD required for operation of the loads 101C to 104C is output from the output terminal 51C_{OUT} to the main wiring portion 1D.

The main wiring portion 1D is a part of the wiring included in the wiring board 200D, and is formed in the conductor layer 201D. In the wiring board 200D, the main wiring portion 1D may be formed to be present in both the conductor layer 201D and the conductor layer 202D different from the conductor layer 201D, but is preferably formed only in the conductor layer 201D on which the power source unit 50C and the load unit 100C are mounted, from the viewpoint of reducing the wiring resistance.

In the second embodiment, the loads 101C to 104C are each a semiconductor package. The load 101C includes the power source terminal 81C. The load 102C includes the power source terminal 82C. The load 103C includes the power source terminal 83C. The load 104C includes the power source terminal 84C. To be noted, the loads 101C to 104C each include an unillustrated ground terminal and an unillustrated signal terminal.

The loads 101C to 104C operate by a direct current voltage. The voltage most suitable for operation is the same for the loads 101C and 102C and is, for example, 1 V. In the second embodiment, the plurality of loads 101C to 104C are connected to the main wiring portion 1D. Therefore, the main wiring portion 1D includes a connecting portion C1D to which the power source terminal 81C of the load 101C is connected, a connecting portion C2D to which the power source terminal 82C of the load 102C is connected, a connecting portion C3D to which the power source terminal 83C of the load 103C is connected, and a connecting portion C4D to which the power source terminal 84C of the load 104C is connected. The plurality of connecting portions C1D to C4D are each an example of a first portion. The plurality of connecting portions C1D to C4D are each, for example, a power source pad.

In the example of the second embodiment, the connecting portion C1D is included in the main line 11D, the connecting portion C2D is included in the main line 12D, the connecting portion C3D is included in the main line 13D, and the connecting portion C4D is included in the main line 14D. The unillustrated ground terminal included in each of the loads 101C to 104C is connected to an unillustrated grounding line.

As described above, the loads 101C to 104C are electrically connected to the power source unit 50C via the main wiring portion 1D and the grounding line, and operate by receiving a direct current voltage based on the ground applied from the power source unit 50C. The most suitable operation voltage is the same for all the loads 101C to 104C and is, for example, 1 V. The most suitable operation voltage for operation of the loads 101C to 104C is used as a standard voltage.

For each of the loads 101C to 104C, an allowable range (allowable voltage fluctuation range) is determined with respect to the standard voltage. The allowable range is, for example, a range of ±30 mV for 1 V. The plurality of loads 101C to 104C are each a load circuit that operates at a low voltage (1 V or less, for example, 1 V), and therefore voltage drop by wiring resistance in the main wiring portion 1D cannot be neglected. Although increasing the area of the main wiring portion 1D to reduce the wiring resistance can be considered, there is a limit in the increase in the area of the main wiring portion 1D for highly densely mounting electronic parts on the wiring board 200D and highly densely providing the wiring of the wiring board 200D.

Therefore, in the second embodiment, the processing module 300D includes a sub wiring portion 2D directly connected to the main wiring portion 1D, and a feedback portion 3D. The sub wiring portion 2D is an example of a second wiring portion. The sub wiring portion 2D is included in the wiring board 200D. The feedback portion 3D is connected to a predetermined portion 20D of the sub wiring portion 2D, and is configured to feed back a voltage corresponding to a voltage VOD generated in the predetermined portion 20D to the feedback terminal 51C_{FB} of the power source unit 50C. The wiring resistance of the wiring included in the sub wiring portion 2D per unit path length is set to be higher than the wiring resistance of the wiring included in the main wiring portion 1D per unit path length.

The main wiring portion 1D includes a plurality of proximity portions T1D to T4D of the same number as the plurality of connecting portions C1D to C4D. The proximity portions T1D to T4D are each an example of a second portion. The sub wiring portion 2D is connected to the plurality of proximity portions T1D to T4D. That is, the plurality of proximity portions T1D to T4D are short-circuited via the sub wiring portion 2D.

Here, the voltage applied to the power source terminal 81C of the load 101C, that is, the voltage of the connecting portion C1D will be denoted by V1D. The voltage applied to the power source terminal 82C of the load 102C, that is, the voltage of the connecting portion C2D will be denoted by V2D. The voltage applied to the power source terminal 83C of the load 103C, that is, the voltage of the connecting portion C3D will be denoted by V3D. The voltage applied to the power source terminal 84C of the load 104C, that is, the voltage of the connecting portion C4D will be denoted by V4D.

The proximity portion T1D is the closest to the connecting portion C1D corresponding thereto among the plurality of connecting portions C1D to C4D on the path of the main wiring portion 1D. The proximity portion T2D is the closest to the connecting portion C2D corresponding thereto among the plurality of connecting portions C1D to C4D on the path of the main wiring portion 1D. The proximity portion T3D is the closest to the connecting portion C3D corresponding thereto among the plurality of connecting portions C1D to C4D on the path of the main wiring portion 1D. The proximity portion T4D is the closest to the connecting portion C4D corresponding thereto among the plurality of connecting portions C1D to C4D on the path of the main wiring portion 1D.

The proximity portion T1D is a portion close to the connecting portion C1D, that is, a portion in the vicinity of the connecting portion C1D. The proximity portion T2D is a portion close to the connecting portion C2D, that is, a portion in the vicinity of the connecting portion C2D. The proximity portion T3D is a portion close to the connecting portion C3D, that is, a portion in the vicinity of the connecting portion C3D. The proximity portion T4D is a portion close to the connecting portion C4D, that is, a portion in the vicinity of the connecting portion C4D.

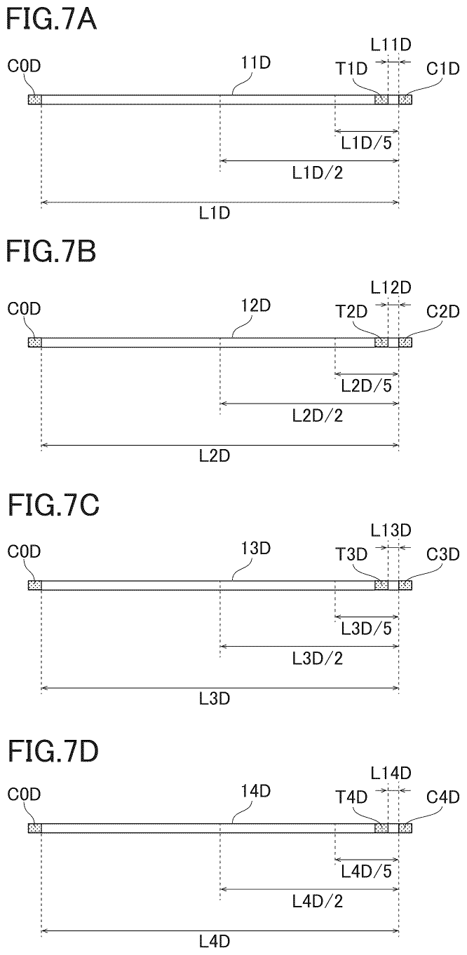

A preferable range in which the proximity portions T1D and T4D are respectively close to the connecting portions C1D to C4D will be described below. FIGS. 7A to 7D are schematic diagrams illustrating paths of the main wiring portions 1D according to the second embodiment. To be noted, in FIGS. 7A to 7D, the path of the main wiring portion 1D is illustrated as a straight line for the sake of convenience of description.

In the main wiring portion 1D, the minimum path length from each of the plurality of proximity portions T1D to T4D to the corresponding one of the connecting portions is preferably smaller than ½ of the minimum path length from the connecting portion C0D to which the output terminal 51C_{OUT} is connected to the corresponding one of the connecting portions.

In addition, in the main wiring portion 1D, the minimum path length from each of the plurality of proximity portions T1D to T4D to the corresponding one of the connecting portions is more preferably smaller than ⅕ of the minimum path length from the connecting portion C0D to which the output terminal 51C_{OUT} is connected to the corresponding one of the connecting portions.

That is, the connecting portion corresponding to the proximity portion T1D is the connecting portion C1D, the connecting portion corresponding to the proximity portion T2D is the connecting portion C2D, the connecting portion corresponding to the proximity portion T3D is the connecting portion C3D, and the connecting portion corresponding to the proximity portion T4D is the connecting portion C4D.

Further, as illustrated in FIG. 7A, a minimum path length L11D from the proximity portion T1D to the connecting portion C1D is preferably smaller than ½, more preferably smaller than ⅕ of a minimum path length L1D from the connecting portion C0D to the connecting portion C1D.

In addition, as illustrated in FIG. 7B, a minimum path length L12D from the proximity portion T2D to the connecting portion C2D is preferably smaller than ½, more preferably smaller than ⅕ of a minimum path length L2D from the connecting portion C0D to the connecting portion C2D.

In addition, as illustrated in FIG. 7C, a minimum path length L13D from the proximity portion T3D to the connecting portion C3D is preferably smaller than ½, more preferably smaller than ⅕ of a minimum path length L3D from the connecting portion C0D to the connecting portion C3D.

In addition, as illustrated in FIG. 7D, a minimum path length L14D from the proximity portion T4D to the connecting portion C4D is preferably smaller than ½, more preferably smaller than ⅕ of a minimum path length L4D from the connecting portion C0D to the connecting portion C4D.

To be noted, in FIGS. 7A to 7D, although the minimum path lengths L1D to L4D are illustrated as equal, these are just illustrated as equal for the sake of convenience of description, and the actual minimum path lengths L1D to L4D do not have to be equal to each other.

The proximity portions T1D to T4D are preferably positioned upstream of the corresponding ones of the connecting portions C1D to C4D in the flow direction of the current, but the configuration is not limited to this. That is, it suffices as long as the proximity portions T1D to T4D are respectively close to the connecting portions C1D to C4D.

The feedback portion 3D includes a feedback line 31D, and a voltage corresponding to the voltage VOD generated in the predetermined portion 20D of the sub wiring portion 2D is supplied to the feedback terminal 51C_{FB} as the feedback voltage VfbD. In the second embodiment, the feedback portion 3D is the feedback line 31D. The feedback line 31D is included in the wiring board 200D.

The feedback line 31D is disposed between the predetermined portion 20D of the sub wiring portion 2D and the feedback terminal 51C_{FB}, and is directly connected to the predetermined portion 20D of the sub wiring portion 2D and the feedback terminal 51C_{FB}. That is, a first end of the feedback line 31D is directly connected to the predetermined portion 20D of the sub wiring portion 2D, and a second end of the feedback line 31D is directly connected to the feedback terminal 51C_{FB}.

To be noted, the feedback portion 3D may include, for example, an unillustrated voltage divider circuit having a configuration similar to that of the voltage divider circuit 240C illustrated in FIG. 3B. In this case, the second end of the feedback line 31D is connected to the feedback terminal 51C_{FB} via the unillustrated voltage divider circuit. The unillustrated voltage divider circuit supplies a voltage obtained by dividing the voltage V0D to the feedback terminal 51C_{FB} as a voltage corresponding to the voltage V0D.

Since a current as large as the current flowing in the main wiring portion 1D does not have to be supplied to the feedback line 31D, a width W3 of the feedback line 31D is preferably smaller than a width W1 of each of the main lines 11D to 14D included in the main wiring portion 1D. That is, preferably W3<W1 holds. In other words, the wiring resistance of the feedback line 31D is preferably higher than the wiring resistance of the main wiring portion 1D.

According to the above-described configuration of the feedback portion 3D, a voltage obtained by subtracting a value of voltage reduction derived from the wiring resistance of the feedback line 31D from the voltage V0D generated in the predetermined portion 20D of the sub wiring portion 2D is supplied to the feedback terminal 51C_{FB} as the feedback voltage VfbD.

As described above, a voltage corresponding to the voltage V0D is supplied to the feedback terminal 51C_{FB} as the feedback voltage VfbD. The power source circuit 52C controls the output voltage VoutD output from the output terminal 51C_{OUT} on the basis of the feedback voltage VfbD supplied to the feedback terminal 51C_{FB}.

To be noted, the current flowing in the feedback line 31D is, for example, about several tens of μA, which is an extremely small value as compared with the current flowing in the main wiring portion 1D, and therefore the voltage reduction derived from the wiring resistance of the feedback line 31D can be neglected. In such a case, the voltage corresponding to the voltage V0D is the voltage V0D.

As described above, according to the second embodiment, since the plurality of the proximity portions T1D to T4D respectively close to the plurality of connecting portions C1D to C4D are short-circuited via the sub wiring portion 2D, a current flows from the high-potential side to the low-potential side via the sub wiring portion 2D, and as a result, the potential difference between the plurality of connecting portions C1D to C4D, that is, the potential difference between the plurality of loads 101C to 104C can be reduced. Therefore, the voltages V1D to V4D applied to the loads 101C to 104C become close to each other.

Further, since a voltage corresponding to the voltage VOD of the predetermined portion 20D of the sub wiring portion 2D is fed back to the feedback terminal 51C_{FB}, the voltages V1D to V4D applied to the loads 101C to 104C can be kept within the respective allowable ranges of the loads 101C to 104C. Therefore, a margin is secured for each of the voltages V1D to V4D with respect to the upper limit voltage or the lower limit voltage of the allowable range of each of the loads 101C to 104C. As a result of this, the voltages V1D to V4D are stably supplied to the loads 101C to 104C, and thus the loads 101C to 104C operate stably.

The sub wiring portion 2D includes a plurality of branch lines 21D to 24D of the same number as the plurality of proximity portions T1D to T4D. That is, the sub wiring portion 2D includes four branch lines 21D to 24D. The plurality of branch lines 21D to 24D are respectively directly connected to the plurality of proximity portions T1D to T4D. Further, the plurality of branch lines 21D to 24D are connected to each other at the predetermined portion 20D.

That is, the first end of each of the branch lines 21D to 24D is directly connected to the corresponding one of the proximity portions, and the respective second ends of the plurality of branch lines 21D to 24D are connected to each other at the predetermined portion 20D.

Specifically, the first end of the branch line 21D is directly connected to the proximity portion T1D, the first end of the branch line 22D is directly connected to the proximity portion T2D, the first end of the branch line 23D is directly connected to the proximity portion T3D, and the first end of the branch line 24D is directly connected to the proximity portion T4D. The second end of the branch line 21D, the second end of the branch line 22D, the second end of the branch line 23D, and the second end of the branch line 24D are connected to each other at the predetermined portion 20D.

The current flowing in each of the branch lines 21D to 24D is preferably smaller than the current flowing in the main wiring portion 1D. Therefore, a width W2 of each of the plurality of branch lines 21D to 24D is preferably smaller than the width W1 of each of the main lines 11D to 14D. That is, W2<W1 preferably holds. In other words, the wiring resistance of each of the branch lines 21D to 24D is preferably higher than the wiring resistance of the main wiring portion 1D.

In addition, the current flowing in the feedback line 31D is preferably smaller than the current flowing in each of the branch lines 21D to 24D. Therefore, the width W3 of the feedback line 31D is preferably smaller than the width W2 of each of the plurality of branch lines 21D to 24D. That is, W3<W2 preferably holds. In other words, the wiring resistance of the feedback line 31D is preferably higher than the wiring resistance of each of the branch lines 21D to 24D.

In addition, the electrical resistance of each of the plurality of branch lines 21D to 24D is preferably 138 mω or less. As a result of this, the difference between the voltages VID to V4D can be reduced more effectively.

In addition, the main wiring portion 1D is disposed in the conductor layer 201D. At least part of the sub wiring portion 2D and at least part of the feedback line 31D are disposed in the conductor layer 202D. That is, the sub wiring portion 2D includes a wiring portion disposed in the conductor layer 202D and a via line interconnecting the conductor layer 201D and 202D. In addition, the feedback line 31D includes a wiring portion disposed in the conductor layer 201D, a wiring portion disposed in the conductor layer 202D, and a via line interconnecting the conductor layer 201D and 202D. As described above, as a result of part of the sub wiring portion 2D and part of the feedback line 31D being disposed in the conductor layer 202D different from the conductor layer 201D, the wiring board 200D can be miniaturized.

To be noted, although the loads 101C to 104C are preferably disposed on the conductor layer 201D on which the power source unit 50C is disposed, at least one of the loads 101C to 104C may be disposed on the conductor layer serving as a surface layer opposite to the conductor layer 201D.

A result of computer simulation performed in a circuit configuration of the processing module 300D according to the second embodiment will be described below.

### Example 2

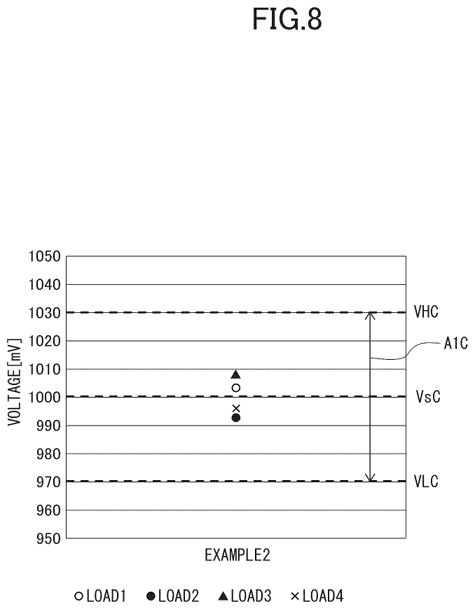

FIG. 8 is an explanatory diagram illustrating a result of simulation by a computer according to Example 2. For the simulation, ANSYS Electronics Desktop 2020 R2 Circuit Design was used. In the simulation, each parameter was set as follows.

The standard voltage VsC of each of the loads 101C to 104C was set to 1 V, that is, 1000 mV. An allowable range A1C of each of the loads 101C to 104C was set to a range of ±30 mV from the standard voltage VsC. That is, the lower limit voltage VLC of the allowable range A1C of each of the loads 101C to 104C was set to 970 mV, and the upper limit voltage VHC of the allowable range A1C of each of the loads 101C to 104C was set to 1030 mV.

The wiring resistance of wiring from the connecting portion C0D to the connecting portion C1D in the main line 11D was set to 15 mω. The wiring resistance of wiring from the connecting portion C0D to the connecting portion C2D in the main line 12D was set to 30 mω. The wiring resistance of wiring from the connecting portion C0D to the connecting portion C3D in the main line 13D was set to 10 mω. The wiring resistance of wiring from the connecting portion C0D to the connecting portion C4D in the main line 14D was set to 25 mω. The operation current of each of the loads 101C to 104C was set to 1 A. In addition, the wiring resistance of each of the branch lines 21D to 24D was set to 60 mω.

In FIG. 8, the voltage V1D applied to the load 101C corresponds to “LOAD 1”, the voltage V2D applied to the load 102C corresponds to “LOAD 2”, the voltage V3D applied to the load 103C corresponds to “LOAD 3”, and the voltage V4D applied to the load 104C corresponds to “LOAD 4”.

In Example 2, as can be seen from the simulation results illustrated in FIG. 8, the voltage difference between the loads 101C to 104C is smaller than in Comparative Examples 1 and 2 and Example 1. As a result of this, whereas the margin of the voltage of the load 102C with respect to the lower limit voltage VLC is 15 mV in Example 1, a margin of 22 mV is secured for the voltage of the load 102C with respect to the lower limit voltage VLC. In addition, the margin of the voltage of the load 103C with respect to the upper limit voltage VHC is also secured.

As described above, a current from the high-potential side to the low-potential side is generated between the loads 101C to 104C due to the sub wiring portion 2D, and as a result of this, the potential difference between the loads 101C to 104C can be reduced. Therefore, the voltages of the loads 101C to 104C can be kept within the allowable range A1C by feeding back the voltage of the predetermined portion 20D of the sub wiring portion 2D to the feedback terminal 51C_{FB}.

In addition, since the main lines 11D to 14D are radially formed and one load is connected to each of the main lines 11D to 14D, the paths of current flowing in the loads 101C to 104C in the main wiring portion 1D do not overlap, and thus the voltage drop in the main wiring portion 1D can be reduced.

### Third Embodiment

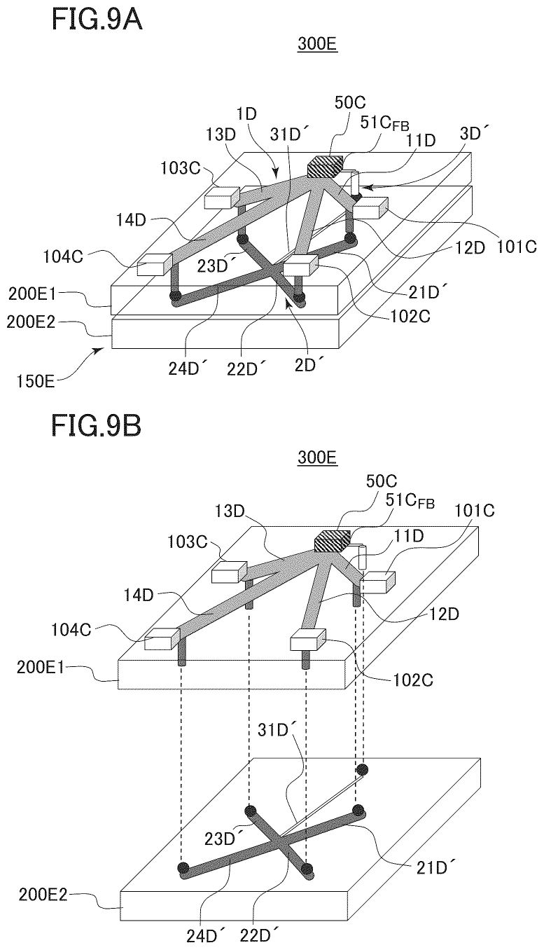

An electronic module included in an electronic device according to a third embodiment will be described. FIG. 9A is a perspective view of a processing module 300E according to the third embodiment. FIG. 9B is an exploded perspective view of the processing module 300E according to the third embodiment. The electronic device of the third embodiment is, for example, a digital camera that is an image pickup apparatus. The digital camera of the third embodiment is different from the digital camera 600C of the first embodiment in that the processing module 300C is replaced by the processing module 300E. The elements of the digital camera of the third embodiment other than the processing module 300E are the same as the elements of the digital camera 600C of the first embodiment other than the processing module 300C, and therefore detailed description of the elements of the digital camera of the third embodiment other than the processing module 300E will be omitted. In addition, among the constituent parts of the processing module 300E, the same constituent parts as the constituent parts included in the processing module 300C of the first embodiment will be denoted by the same reference signs used in the first embodiment, and description thereof will be omitted. In addition, among the constituent parts of the processing module 300E, the same constituent parts as the constituent parts included in the processing module 300D of the second embodiment will be denoted by the same reference signs used in the second embodiment, and description thereof will be omitted.

Although a case where the wiring portions 1C and 2C and the feedback line 31C are included in the one wiring board 200C has been described in the first embodiment and a case where the wiring portions 1D and 2D and the feedback line 31D are included in the one wiring board 200D has been described in the second embodiment, the configuration is not limited to these.

The processing module 300E of the third embodiment includes the power source unit 50C, the load unit 100C, and a wiring board unit 150E. The configuration of the power source unit 50C and the load unit 100C is as described in the first embodiment. The wiring board unit 150E includes a plurality of wiring boards. The plurality of wiring boards are arranged to be layered on each other. The plurality of wiring boards include two wiring board 200E1 and 200E2. In the third embodiment, the plurality of wiring boards are the two wiring boards 200E1 and 200E2. The wiring board 200E1 is an example of a first wiring board, and the wiring board 200E2 is an example of a second wiring board.

The two wiring boards 200E1 and 200E2 are bonded via a plurality of solder bonding members. The wiring board 200E1 is disposed on the wiring board 200E2, and the power source unit 50C and the load unit 100C are disposed on the wiring board 200E1. The load unit 100C includes the four loads 101C to 104C.

The wiring boards 200E1 and 200E2 are each a printed wiring board, and are each a rigid wiring board. The power source unit 50C and the load unit 100C are disposed on the wiring board 200E1 among the wiring boards 200E1 and 200E2.

The processing module 300E includes the main wiring portion 1D that is a main part of a power source wiring portion for supplying a voltage to each of the plurality of loads 101C to 104C of the load unit 100C, and an unillustrated grounding line. The main wiring portion 1D is an example of a first wiring portion. The configuration of the main wiring portion 1D is as described in the second embodiment. That is, the main wiring portion 1D includes the plurality of main lines 11D to 14D arranged radially.

The processing module 300E includes a sub wiring portion 2D′ directly connected to the main wiring portion 1D, and a feedback portion 3D′. The sub wiring portion 2D′ is an example of a second wiring portion. The feedback portion 3D′ includes a feedback line 31D′.

Although the placed position and shape of the sub wiring portion 2D′ are different from the placed position and shape of the sub wiring portion 2D of the second embodiment, the configuration of the sub wiring portion 2D′ is approximately the same as the configuration of the sub wiring portion 2D. In addition, although the placed position and shape of the feedback line 31D′ are different from the placed position and shape of the feedback line 31D of the second embodiment, the configuration of the feedback line 31D′ is approximately the same as the configuration of the feedback line 31D.

The main wiring portion 1D, the sub wiring portion 2D′, and the feedback line 31D′ are included in the wiring board unit 150E. The entirety of the main wiring portion 1D is included in the wiring board 200E1. At least part of the sub wiring portion 2D′ is included in the wiring board 200E2. At least part of the feedback line 31D′ is included in the wiring board 200E2. That is, the sub wiring portion 2D′ and the feedback line 31D′ are disposed to be present in both the two wiring boards 200E1 and 200E2.

The sub wiring portion 2D′ includes four branch lines 21D′ to 24D′. The four branch lines 21D′ to 24D′ each branch from the main wiring portion 1D and each include a via line included in the wiring board 200E1, a solder bonding member, and a wiring pattern included in the wiring board 200E2. The feedback line 31D′ includes a wiring pattern included in the wiring board 200E2, a solder bonding member, and a via line and a wiring pattern that are included in the wiring board 200E1.

According to the third embodiment, since the sub wiring portion 2D′ and the feedback line 31D′ are disposed to be present in both the wiring boards 200E1 and 200E2, electronic parts can be highly densely mounted on each of the wiring boards 200E1 and 200E2, and therefore the wiring board unit 150E, that is, the processing module 300E can be miniaturized. Further, the difference in the voltage supplied to each of the loads 101C to 104C can be reduced while miniaturizing the processing module 300E. Therefore, the operation of each of the loads 101C to 104C is stabilized.

### Example 3

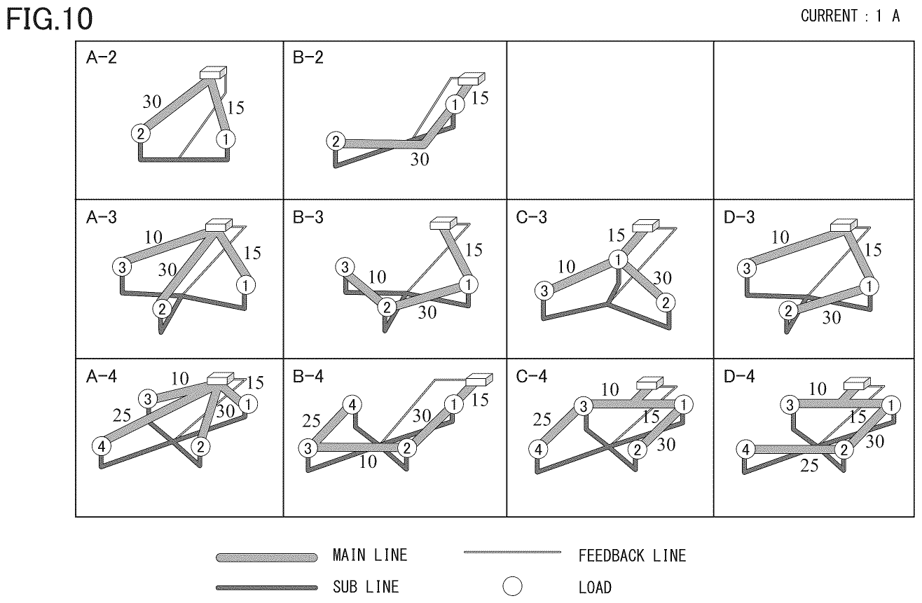

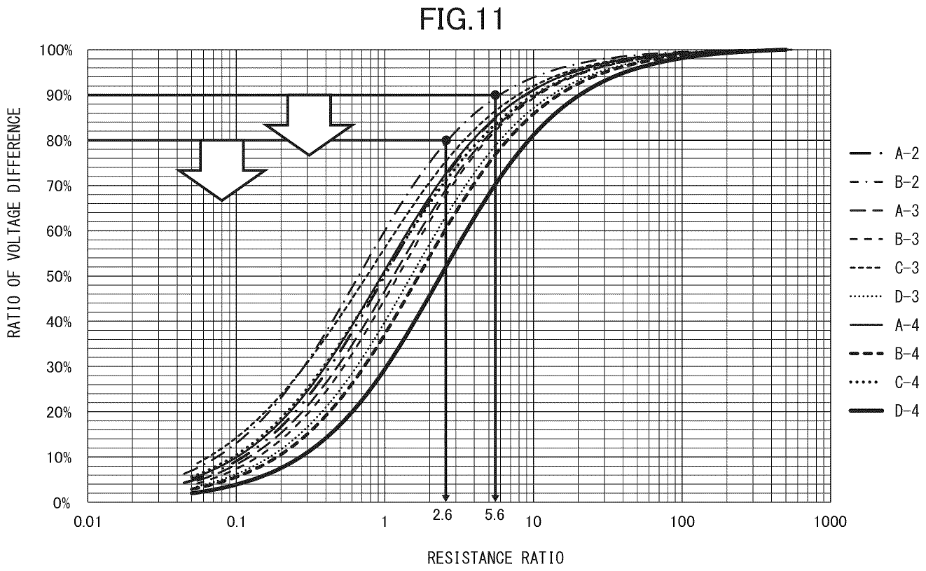

Simulation was performed by a computer by changing the number of loads and the pattern of the main wiring portion serving as a first wiring portion. FIG. 10 is an explanatory diagram of samples A-2, A-3, A-4, B-2, B-3, B-4, C-3, C-4, D-3, and D-4 for which simulation was performed by a computer according to Example 3. FIG. 11 is an explanatory diagram illustrating results of simulation by the computer according to Example 3. For the simulation, ANSYS Electronics Desktop 2020 R2 Circuit Design was used.

In each sample illustrated in FIG. 10, each circle represents a load, and a number given to the load is described in the circle. In addition, a number described adjacent to the main line indicates the wiring resistance in the unit of mω. The current flowing in each load was set to 1 A.

The sample A-2 has a configuration in which two loads are connected to the main wiring portion. The main wiring portion includes two main lines radially extending from the power source unit.

The sample A-3 has a configuration in which three loads are connected to the main wiring portion. The main wiring portion includes three main lines radially extending from the power source unit.

The sample A-4 has a configuration in which four loads are connected to the main wiring portion. The main wiring portion includes four main lines radially extending from the power source unit.

The sample B-2 has a configuration in which two loads are connected to the main wiring portion. The main wiring portion is one main line having a unicursal shape.

The sample B-3 has a configuration in which three loads are connected to the main wiring portion. The main wiring portion is one main line having a unicursal shape.

The sample B-4 has a configuration in which four loads are connected to the main wiring portion. The main wiring portion is one main line having a unicursal shape.

The sample C-3 has a configuration in which three loads are connected to the main wiring portion. The main wiring portion includes a first main line and two second main lines branching from the first main line. One load is connected to the first main line, and one load is connected to each of the two second main lines.

The sample C-4 has a configuration in which four loads are connected to the main wiring portion. The main wiring portion includes a first main line and two second main lines branching from the first main line. Two loads are connected to each of the two second main lines.

The sample D-3 has a configuration in which three loads are connected to the main wiring portion. The main wiring portion includes two main lines. One load is connected to one of the two main lines, and two loads are connected to the other of the two main lines.

The sample D-4 has a configuration in which four loads are connected to the main wiring portion. The main wiring portion includes a first main line and two second main lines branching from the first main line. One load is connected to one of the two second main lines, and three loads are connected to the other of the two second main lines.

The wiring resistance of the main wiring was set as illustrated in FIG. 10, and simulation was performed while changing the wiring resistance of each branch line. FIG. 11 illustrates the simulation results. In FIG. 11, the horizontal axis represents a resistance ratio obtained by dividing the sum of the electric resistance of the branch lines included in the sub wiring portion by the sum of the electric resistance of the main lines included in the main wiring portion. The branch lines included in the sub wiring portion was set to the same electric resistance, and the same electric resistance was changed from 1 mω to 10ω. Therefore, the sum of the electric resistance of the branch lines of the sub wiring portion was changed in a range of 2 mω to 20 ω for the samples A-2 and B-2, a range of 3 mω to 30 ω for the samples A-3, B-3, C-3, and D-3, and a range of 4 mω to 40 ω for the samples A-4, B-4, C-4, and D-4. The vertical axis represents the ratio of voltage difference obtained by dividing the maximum voltage difference occurring between the plurality of loads in each sample by the maximum voltage difference occurring between the plurality of loads in the case where the sum of resistance of the branch lines of the sub wiring portion of each sample was the highest. To be noted, the ratio of the voltage difference is shown in percentage in FIG. 11.

As illustrated in FIG. 11, the ratio of the voltage difference was the highest for the sample B-2 for the same resistance ratio. Therefore, the sample B-2 was set as the target.

As illustrated in FIG. 11, the resistance ratio of the sum of the electric resistance of the branch lines of the sub wiring portion to the sum of the electric resistance of the branch lines of the main wiring portion is preferably equal to or less than 5.6 at which the ratio of the voltage difference is 90%, and is more preferably equal to or less than 2.6 at which the ratio of the voltage difference is 80%.

To be noted, since the ratio of voltage difference saturates when the resistance ratio of the sum of the electric resistance of the branch lines of the sub wiring portion to the sum of the electric resistance of the branch lines of the main wiring portion is about 0.1, the resistance ratio of the sum of the electric resistance of the branch lines of the sub wiring portion to the sum of the electric resistance of the branch lines of the main wiring portion is preferably 0.1 or more.

In addition, the electric resistance of the branch lines of each sample in the case where the ratio of the voltage difference was 90% were as follows.
A-2: 138 mω
B-2: 208 mω
A-3: 181 mω
B-3: 190 mω
C-3: 138 mω
D-3: 234 mω
A-4: 166 mω
B-4: 282 mω
C-4: 190 mω
D-4: 389 mω

In the case where the ratio of the voltage difference was 90%, the minimum value of the electric resistance of the branch lines in the plurality of samples was 138 mω. Therefore, the electric resistance of the branch lines is preferably 138 mω or less.

The present invention is not limited to the embodiments described above, and can be modified in many ways within the technical concept of the present disclosure. In addition, the effects described in the embodiments are merely enumeration of the most preferable effects that can be obtained from the present invention, and the effects of the present invention are not limited to those described in the embodiments.

Although a case where the electronic module of the present disclosure is applied to an image pickup apparatus such as a digital camera has been described in the embodiments described above, the application is not limited to this. The electronic module of the present disclosure is also applicable to an image pickup apparatus of a mobile communication device or a wearable device such as a smartphone, a tablet PC, or a gaming device. In addition, the electronic module of the present disclosure is also applicable to an electronic device that is not an image pickup apparatus, for example, an image forming apparatus such as a printer, a copier, a facsimile machine, or a multifunctional apparatus having functions of these.

According to the present disclosure, voltage can be stably supplied to each load.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2022-189005, filed Nov. 28, 2022, which is hereby incorporated by reference herein in its entirety.

What is claimed is:

1. An electronic module comprising:
a plurality of loads;
a first wiring portion used for supplying a voltage to the plurality of loads and including a plurality of first portions to which the plurality of loads are respectively connected, and a plurality of second portions each closest to a corresponding one of the plurality of first portions;
a second wiring portion connected to the plurality of second portions;
a power source unit including a feedback terminal, an output terminal connected to the first wiring portion, and a power source circuit configured to control a voltage to be output from the output terminal on a basis of a feedback voltage supplied to the feedback terminal; and
a feedback portion configured to supply a voltage corresponding to a voltage generated in a predetermined portion of the second wiring portion to the feedback terminal as the feedback voltage,
wherein in the first wiring portion, a minimum path length from each of the plurality of second portions to the corresponding one of the plurality of first portions is smaller than ½ of a minimum path length from a part of the first wiring portion connected to the output terminal to the corresponding one of the plurality of first portions.

2. The electronic module according to claim 1, wherein, in the first wiring portion, the minimum path length from each of the plurality of second portions to the corresponding one of the plurality of first portions is smaller than ⅕ of a minimum path length from the part of the first wiring portion connected to the output terminal to the corresponding one of the plurality of first portions.

3. The electronic module according to claim 1, wherein a ratio of a sum of electric resistance of wiring included in the second wiring portion to a sum of electric resistance of wiring included in the first wiring portion is 5.6 or less.

4. The electronic module according to claim 1,
wherein the plurality of loads include a first load and a second load, and
wherein the first wiring portion includes one line including a portion of the plurality of first portions to which the first load is connected, and a portion of the plurality of first portions to which the second load is connected.

5. The electronic module according to claim 1,
wherein the plurality of loads includes a first load and a second load, and
wherein the first wiring portion includes a line including a portion of the plurality of first portions to which the first load is connected, and a line including a portion of the plurality of first portions to which the second load is connected.

6. The electronic module according to claim 1, wherein the second wiring portion includes a plurality of branch lines respectively connected to the plurality of second portions, and the plurality of branch lines are connected to each other at the predetermined portion.

7. The electronic module according to claim 6, wherein a width of each of the plurality of branch lines is smaller than a width of a line included in the first wiring portion.

8. The electronic module according to claim 6, wherein the plurality of branch lines each have an electric resistance of 138 mω or less.

9. The electronic module according to claim 1, wherein the feedback portion includes a feedback line connected to the predetermined portion.

10. The electronic module according to claim 9, wherein a width of the feedback line is smaller than a width of a line included in the first wiring portion.

11. The electronic module according to claim 6,
wherein the feedback portion includes a feedback line connected to the predetermined portion, and
wherein a width of the feedback line is smaller than a width of each of the plurality of branch lines.

12. The electronic module according to claim 9, further comprising:
a wiring board including a first conductor layer and a second conductor layer,
wherein the first wiring portion and the second wiring portion are disposed in the first conductor layer, and
wherein at least part of the feedback line is disposed in the second conductor layer.

13. The electronic module according to claim 9, further comprising:
a wiring board including a first conductor layer and a second conductor layer,
wherein the first wiring portion is disposed in the first conductor layer, and
wherein at least part of the second wiring portion and at least part of the feedback line are disposed in the second conductor layer.

14. The electronic module according to claim 1, further comprising:
a wiring board unit including a first wiring board and a second wiring board,
wherein the first wiring portion and the second wiring portion are disposed in the wiring board unit.

15. The electronic module according to claim 9, further comprising:
a wiring board unit including a first wiring board and a second wiring board,
wherein the first wiring board is disposed on the second wiring board,
wherein the power source unit and the plurality of loads are mounted on the first wiring board,
wherein the first wiring portion is included in the first wiring board, and
wherein at least part of the second wiring portion and at least part of the feedback line is included in the second wiring board.

16. An electronic device comprising:
the electronic module according to claim 1; and
a casing in which the electronic module is disposed.

17. The electronic device according to claim 16, wherein the electronic device is an image pickup apparatus.
